(19) United States
(12) Patent Application Publication
(10) Pub. No.: US 2011/0175594 A1
(43) Pub. Date: Jul. 21, 2011

(54) APPARATUS FOR MEASURING THE MAGNITUDE OF AN ELECTRIC FIELD

(75) Inventors: Hiroki Funato, Yokohama (JP); Masayoshi Takahashi, West Bloomfield, MI (US); Liang Shao, Ann Arbor, MI (US); Takashi Suga, Yokohama City (JP)

(73) Assignee: Hitachi, Ltd., Tokyo (JP)

(21) Appl. No.: 12/689,476

(22) Filed: Jan. 19, 2010

(51) Int. Cl. G01R 29/00

(52) U.S. Cl. 324/72

(57) ABSTRACT

An apparatus for measuring the magnitude of an electric field having an antenna open to the field. The antenna is connected to a data converter which generates an output signal proportional to the magnitude or power of the electric field detected by the antenna. The data converter provides an output signal to a memory unit which stores the magnitude of the electric field. The data converter and memory unit are contained within a housing and the antenna protrudes outwardly from that housing so that the housing and antenna may be positioned within the area of the electric field.

### BACKGROUND OF THE INVENTION

I. Field of the Invention

The present invention provides an apparatus for measuring the magnitude of an electric field.

II. Description of Related Art

There are many situations where it is desirable to measure the magnitude or power of an electric field in a particular area. For example, in hybrid automotive vehicles and electric automotive vehicles, the power of the electric field within the power inverter housing for the vehicle is generally quite high. Furthermore, excessive electric fields within the power inverter housing may interfere with other functions of the automotive vehicle, such as radio reception and the like.

There have, however, been previously known devices for measuring the strength or power of an electric field. These previously known devices typically comprise a probe which is placed within the area of interest. The probe is then electrically connected through a cable to an electric field measuring circuit which is removed from the test area.

One disadvantage of these previously known devices, however, is that the electric field of interest is often contained within a closed enclosure, such as the housing for a power inverter of a hybrid or electric vehicle. Consequently, in order to electrically connect the probe to the electric field measuring circuitry, it is necessary to either drill holes through the enclosure through which the antenna cable extends, or to leave the enclosure lid at least partly open so that the antenna probe cable extends between the lid and the enclosure.

In each case, i.e. drilling holes through the enclosure for the antenna probe cable or leaving the enclosure partly open, changes the actual electric field distribution within the enclosure. Consequently, inaccurate readings of the electric field within the enclosure can result.

### SUMMARY OF THE PRESENT INVENTION

The present invention provides an apparatus for measuring the magnitude of an electric field which overcomes the above-mentioned disadvantages of the previously known devices.

In brief, the device of the present invention comprises an antenna having an output which is connected to a data converter. The data converter then generates an output signal which is proportional to the magnitude of the electric field detected by the antenna. The output from the data converter is then coupled to a memory unit which stores the magnitude of the electric field.

Unlike the previously known devices, however, the data converter and memory unit are self-contained within a housing and the antenna protrudes outwardly from that housing. Consequently, in order to measure the electric field within an enclosure, such as an enclosure for the power inverter for a hybrid or electric vehicle, the entire apparatus of the present invention is positioned within the desired location within the enclosure and the enclosure is then closed or secured together in its normal fashion. As such, the apparatus of the present invention completely eliminates the previously known requirement of drilling holes within the enclosure and/or leaving the enclosure partly open which may affect the electric field distribution.

After the inverter or other circuitry within the enclosure is operated in the desired fashion, the housing for the apparatus of the present invention is simply removed from the enclosure and the data stored on the memory unit is downloaded or read in any conventional fashion.

Optionally, the apparatus of the present invention contains a display device, also contained within the housing, which displays the magnitude of the electric field. In that event, typically the display device will display the maximum measured power for the electric field during the electric field measuring test run.

### BRIEF DESCRIPTION OF THE DRAWING

A better understanding of the present invention will be had upon reference to the following detailed description when read in conjunction with the accompanying drawing, wherein like reference characters refer to like parts throughout the several views, and in which:

FIG. 1 is an elevational view illustrating a preferred embodiment of the present invention;

FIG. 2 is an exploded view similar to FIG. 1, but with the top of the housing removed;

FIG. 3 is a block diagrammatic view illustrating a preferred embodiment of the present invention;

FIG. 4 is a view similar to FIG. 3 but illustrating a modification thereof;

FIG. 5 is a view similar to FIG. 3, but illustrating a modification thereof;

FIG. 6 is a block diagrammatic view similar to FIG. 3, but illustrating a modification thereof; and

FIG. 7 is a block diagrammatic view similar to FIG. 3, but illustrating a modification thereof.

### DETAILED DESCRIPTION OF PREFERRED EMBODIMENTS OF THE PRESENT INVENTION

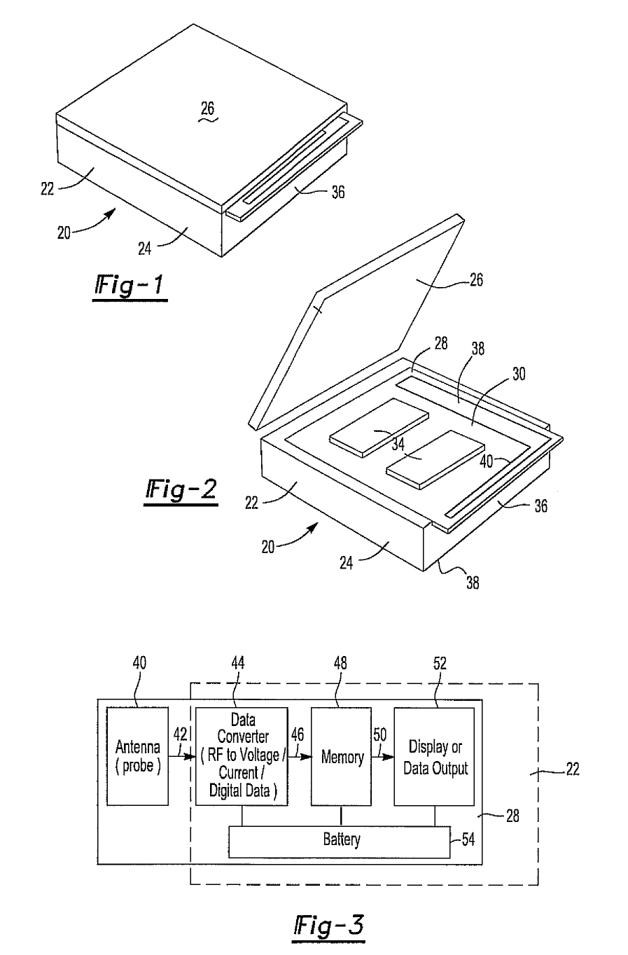

With reference first to FIGS. 1 and 2, a preferred embodiment of an apparatus 20 for measuring the magnitude or power of an electric field is shown. The apparatus 20 includes a housing 22 which is shielded from an electric field in any conventional fashion. For example, the housing 22 may be constructed of metal or, alternatively, may be wrapped in metallic foil such that the contents of the housing 20 are shielded from an electric field.

The housing 22 includes a main body 24 as well as a lid 26. With the lid 26 attached across the top of the main body 24, an interior cavity 28 is formed between the lid 26 and the housing main body 24.

A printed circuit board 30 is positioned within the cavity 28 of the housing 22. Electronic components 34, which will subsequently be described in greater detail, are mounted to the printed circuit board 30 in the conventional fashion.

Still referring to FIGS. 1 and 2, an end 36 of the printed circuit board 30 extends through a slot in the housing 22 so that the end 36 of the printed circuit board is positioned exteriorly of the housing 22. One or more foil lines 38 are printed on the end 36 of the printed circuit board 30 so that these foil line or lines form an antenna 40 on the printed circuit board end 36 which is open to an electric field surrounding the housing 22.

With reference now to FIG. 3, a block diagrammatic view of a preferred embodiment of the present invention is shown. The antenna 40 has an output 42 which is connected as an input signal to a data converter 44 mounted to the printed circuit board 30. The data converter converts the RF input received from the antenna 40 so that an output signal 46 from the data converter is proportional to the magnitude or power of the RF field detected by the antenna 40. The data converter 44, furthermore, may vary either the current or voltage at its output 46 in a manner proportional to the electric field sensed by the antenna 40. Alternatively, the data converter 44 may include an analog-digital converter so that its output signal on its output 46 comprises a digital signal which varies in value in a manner proportional to the strength or power of the electric field surrounding the antenna 40.

The output 46 from the data converter 44 is coupled as an input signal to digital memory 48. In most cases, the maximum or highest electric field detected by the antenna 40 is desired for engineering design purposes. In that event, the data stored by the memory 48 will store the maximum electric field detected by the antenna 40 during the test run. Alternatively, however, the data converter 44 may be programmed to store a plurality of electric field measurements during sequential time increments during the test run.

Still referring to FIG. 3, the memory 48 optionally provides an output signal on its output 50 to a display or data output circuit 52. If a display unit is utilized, any conventional display, such as an LCD, LED bar, or the like may be employed. Conversely, where the circuit 52 is a data output signal, the circuit 52 merely provides an output buffer from the memory 48 for downloading the data in the memory 48 to a computer following the test run.

It will be understood, however, that the display or data output circuit 52 is optional, in which case the data is merely is merely stored on the memory 48. Following the test run, the data from the memory 48 may be downloaded using any other conventional equipment.

The data converter 44, memory 48 and, if present, the display or data output 52 are all mounted on the printed circuit board 22. As previously described, the antenna 40 comprises a foil line or pattern on the printed circuit board 28. Additionally, a battery 54 is also electrically contained in the housing 22 and connected to the printed circuit board 28 and provides power to the data converter 44, memory 48 and display or data output 52.

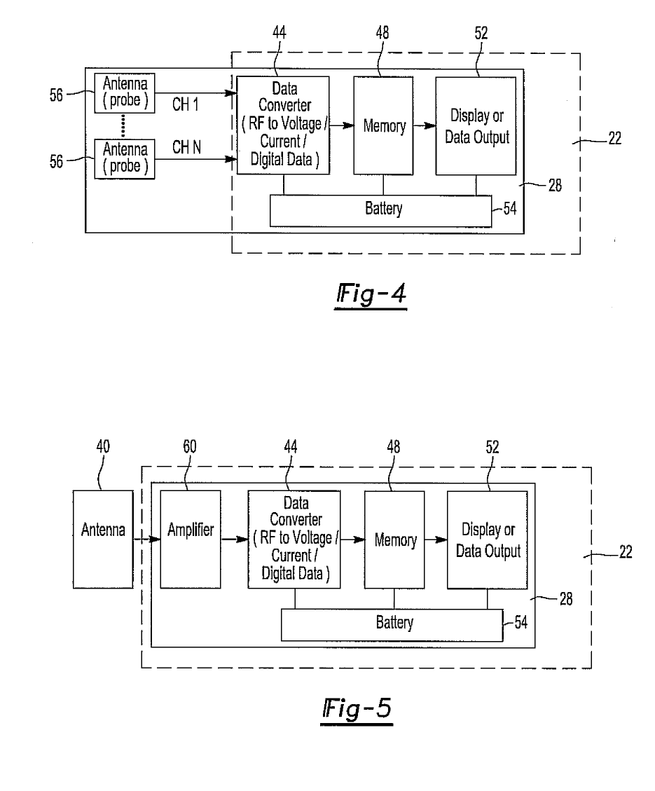

With reference now to FIG. 4, a modification to the present invention is shown. The modification of the apparatus of the present invention illustrated in FIG. 4 is substantially the same as that illustrated in FIG. 3, except that two or more antennas 56 are formed on the printed circuit board 30 as foil patterns. Each antenna 56 has an output coupled as an input signal to the data converter 44.

There are several advantages to using plural antennas 56 rather than a single antenna 56. For example, the use of plural antennas 56 allows the antennas 56 to be oriented in different directions so that the magnitude or power of the electric field along different axes may be measured. Similarly, the use of plural antennas 56 allows different antennas to be tuned for different frequency ranges. Similarly, different types of antennas may be used, such as monopoles, dipoles, patterns, patch, and the like.

In the event that multiple antennas 56 are employed with the device of the present invention, the data converter 44 preferably comprises a PIC (peripheral interface controller) for selecting which of the multiple antennas 56 for measurement and storage in the memory 48. Such PICs may also include an analog/digital converter to provide a digital output signal to the memory 48 of the magnitude of the electric field.

With reference now to FIG. 5, a still further modification of the present invention is shown in which an amplifier 60 is operatively coupled between the antenna 40 and the data converter 44. The amplifier 60 is powered by the battery 54 and increases the signal from the antenna 40 for increased accuracy during relatively low power electric field measurements.

With reference now to FIG. 6, a still further embodiment of the present invention is shown in which the antenna 40 is coupled through a DC blocking capacitor 70 to the amplifier 60. The amplifier 60, after amplifying the input from the antenna 40, generates an output signal to an RF power detector 72. A DC blocking capacitor 74 is connected in series between the amplifier 60 and the power detector 72.

The power detector 72 forms the data converter and generates an analog output signal on its output 76 that is proportional to the power of the electric field detected by the antenna 40. That output signal is coupled to a peripheral interface controller 76 which includes both an analog-to-digital converter as well as memory. Consequently, the PIC 76 together with the power detector 72 perform the equivalent functions of the data converter 44 and memory 48 (FIG. 3).

Still referring to FIG. 6, a resistor 80 is optionally connected between the antenna and ground. This resistor 80 is selected to vary the impedance of the input signal to the amplifier 60. Additionally, a capacitor 82 extending between the input to the PIC 76 and ground eliminates or at least reduces ripple of the input signal to the PIC 76.

The PIC 76 also includes a data output line 84 which, once active, provides a digital series output signal on its output 86. This output 86 is then connected to a computer or other device for downloading the data from the PIC 76.

An input 88 on the PIC 76 controls the initiation of the data output from the PIC 76 to its output 86. Momentary depression of a switch 90 momentarily grounds the trigger input 92 of the PIC 76 and initiates the data transfer from the PIC 76 to its output 86.

In many cases, it is only necessary that the memory record the highest electric field detected by the antenna, i.e. the peak for the electric field during the test run. However, in other cases, it would be desirable to record the RF energy at predetermined time increments during a test period.

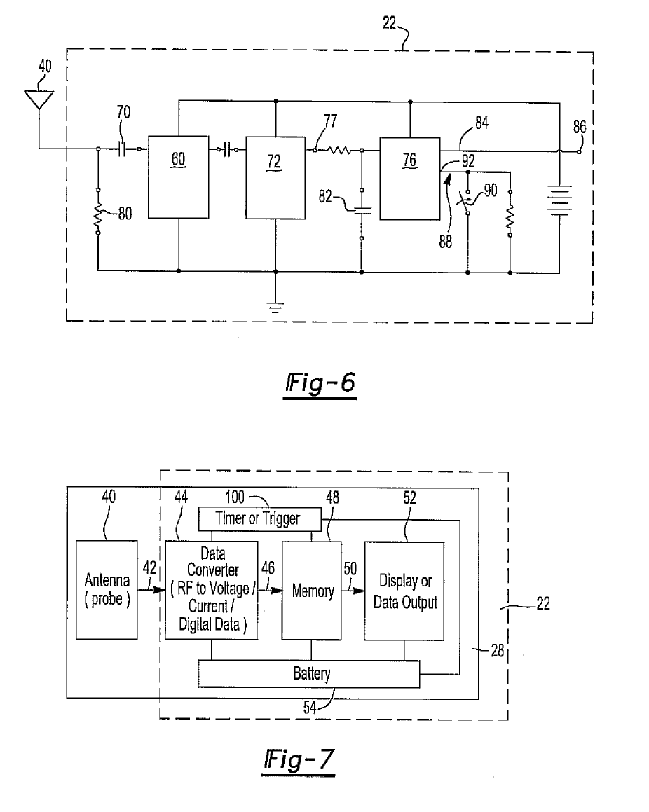

With reference then to FIG. 7, a still further modification of the present invention is shown in which the apparatus of the present invention includes a timer or trigger 100 having outputs to both the data converter 44 and memory 48. When activated, the trigger 100 initiates the recordation of the instantaneous RF power detected by the antenna 40 in the memory 48 at predetermined time segments over the test period. Each recordation of data in the memory 48 may optionally include a time stamp.

The timer or trigger 100, which includes an internal clock, may record continuously after power up in predetermined time increments. Conversely, the apparatus may record the sensed magnitudes of the RF power in predetermined increments of time following an external trigger. For example, the trigger may become active only after an electric field in excess of a predetermined minimum is detected. That, furthermore, would be particularly advantageous since a device could be inserted into the desired area for the RF power measurements but would not begin to record the RF power until after the test period had begun.

From the foregoing, it can be seen that the present invention provides a simple and highly effective self-contained apparatus for measuring RF power. Having described our invention, however, many modifications thereto will become apparent to those skilled in the art to which it pertains without deviation from the spirit of the invention as defined by the scope of the appended claims.

We claim:

1. Apparatus for measuring the magnitude of an electric field comprising:
a housing,
an antenna having an output, said antenna protruding from but attached to said housing,
a data converter having an input connected to said antenna output and an output, said data converter generating an output signal on said data converter output proportional to the magnitude of the electric field detected by said antenna, and
a memory unit having an input connected to said data converter output which stores the magnitude of the electric field,
wherein said data converter and said memory unit are contained within said housing.

2. The apparatus as defined in claim 1 wherein said data converter converts a radio frequency on its input to a digital value for storage in said memory unit.

3. The apparatus as defined in claim 1 and comprising a trigger circuit for initiating data recordation at spaced time intervals.

4. The apparatus as defined in claim 3 wherein said trigger initiates data recordation when the sensed electric field exceeds a predetermined minimum.

5. The apparatus as defined in claim 1 and comprising two antennas, said data converter generating a pair of output signals representative of the magnitude of the electric field of each antenna, said data converter output signals being stored in said memory unit.

6. The apparatus as defined in claim 1 wherein said antennas are oriented in different directions.

7. The apparatus as defined in claim 1 and comprising an amplifier operatively disposed between said antenna and said data converter.

8. The apparatus as defined in claim 1 and comprising a data display connected to said memory unit which displays the contents of said memory unit.

9. The apparatus as defined in claim 1 wherein said data converter and said memory unit are mounted to a printed circuit board.

10. The apparatus as defined in claim 9 wherein said antenna comprises a foil line on said printed circuit board.

11. The apparatus as defined in claim 1 and including an output circuit connected to said memory unit, said output circuit operable to retrieve data from said memory unit.

12. The apparatus as defined in claim 10 wherein said output circuit comprises a PIC controller.

13. The apparatus as defined in claim 1 wherein said data converter comprises an RF power detector.

14. The apparatus as defined in claim 1 wherein said housing is shielded from electric fields.

15. The apparatus as defined in claim 16 and further comprising the step of outputting data from said memory.

16. A method for measuring radio frequency electric fields comprising the steps of:
detecting an electric field with an antenna,
converting said detected electric field to a value which varies proportionately with the strength of the detected electric field, and
storing said value in a memory unit.

17. The method as defined in claim 16 wherein said converting step comprises the step of converting the strength of the detected electric field to a digital number.

18. Apparatus for measuring the magnitude of an electric field comprising:
a housing,
an antenna having an output, said antenna protruding from but attached to said housing,
an electric field power detector and a PIC, said detector having an input connected to said antenna output and an analog output connected as an input signal to said PIC, said detector generating a signal on its output proportional to the magnitude of the electric field detected by said antenna, and
said PIC having an analog/digital converter and digital memory,
wherein said detector and said PIC are contained in said housing.

19. The apparatus as defined in claim 18 wherein said PIC includes an output port for outputting data from said PIC memory.
